(19) United States
(12) Patent Application Publication
(10) Pub. No.: US 2019/0131029 A1
(43) Pub. Date: May 2, 2019

(54) CONDUCTIVE PASTE FOR BONDING AND MANUFACTURING METHOD OF ELECTRIC DEVICE USING THEREOF

(71) Applicant: E I DU PONT DE NEMOURS AND COMPANY, Wilmington, DE (US)

(72) Inventor: Yumi Matsuura, Kanagawa (JP)

(21) Appl. No.: 16/173,393

(22) Filed: Oct. 29, 2018

(30) Foreign Application Priority Data
Nov. 1, 2017 (JP) 2017-212139

(51) Int. Cl. H01B 1/22; H05K 1/09; H01L 21/48

(52) U.S. Cl. CPC H01B 1/22; H05K 2201/035; H01L 21/4867; H05K 1/092

(57) ABSTRACT

The invention relates to a method of manufacturing an electronic device. The method comprises the steps of: preparing a substrate comprising an electrically conductive layer; applying a conductive paste on the electrically conductive layer; wherein the conductive paste comprises 100 parts by weight of a metal powder, 5 to 20 parts by weight of a solvent, and 0.07 to 3 parts by weight of a branched higher fatty acid; mounting an electrical component on the applied conductive paste; and heating the conductive paste to bond the electrically conductive layer and the electrical component. The invention also provides the conductive paste.

### FIELD OF THE INVENTION

This invention relates to a conductive paste for bonding and a method for manufacturing an electronic device using the conductive paste.

### TECHNICAL BACKGROUND OF THE INVENTION

An electronic device comprises an electrical component such as a semiconductor chip that is bonded to an electrically conductive layer on a substrate using a conductive paste.

The electrical component is physically and electrically connected to the electrically conductive layer by applying conductive paste onto the electrically conductive substrate, mounting the electrical component on the conductive paste, and then heating the conductive paste. It has been found that currently used manufacturing processes and pastes frequently do not provide sufficient adhesion between the mounted electrical component and the conductive paste layer before bonding during the manufacturing process and the electrical component may peel off and cause defects in the electronic device.

JP2014-235942 discloses a joining material which prevents formation of aggregate on the surface of a copper substrate immediately after coating or after the lapse of a specified time from coating and prevents deterioration of the jointing power due to occurrence of cracks in a pre-dried film. It also discloses a method of joining electronic parts by using the joining material. The joining material consists of a silver paste comprising silver fine particles, a solvent, 2-butoxyethoxyacetic acid (BEA) as a dispersant and benzotriazole (BTA) as a reaction inhibitor. It is applied on a copper substrate. An electronic part is mounted applied joining material. The bonding structure is heated while pressure is applied to the electronic parts to sinter the silver in the silver paste so as to form a silver joining layer so that the electronic part is joined to the copper substrate through the silver joining layer.

### SUMMARY OF THE INVENTION

An object of the present invention is to provide a conductive paste that sufficiently bonds to an electronic component after heating, and a method of manufacturing an electronic device using the conductive paste. Another object of the present invention is to provide a conductive paste that sufficiently adhere to an electronic component, before heating, during the manufacturing process, and a method of manufacturing an electronic device using the conductive paste.

An aspect of the invention relates to a method of manufacturing an electronic device comprising the steps of:

preparing a substrate comprising an electrically conductive layer;
applying a conductive paste on the electrically conductive layer; wherein the conductive paste comprises 100 parts by weight of a metal powder, 5 to 20 parts by weight of a solvent, and 0.07 to 3 parts by weight of a branched higher fatty acid;
mounting an electrical component on the applied conductive paste; and
heating the conductive paste to bond the electrically conductive layer and the electrical component.

Another aspect of the invention relates to a conductive paste for bonding, comprising 100 parts by weight of the metal powder, 5 to 20 parts by weight of a solvent, and 0.07 to 3 parts by weight of a branched higher fatty acid.

The electronic component can sufficiently bond to the conductive layer after heating. The electronic component can sufficiently adhere to the conductive paste layer before the heating and bonding.

### BRIEF DESCRIPTION OF DRAWINGS

FIG. 1 is a schematic drawing showing an example of a cross section of an electronic device.

FIG. 2 depicts one example of relation between the branched fatty acid and the metal particles in the conductive paste.

### DESCRIPTION OF THE PREFERRED EMBODIMENTS

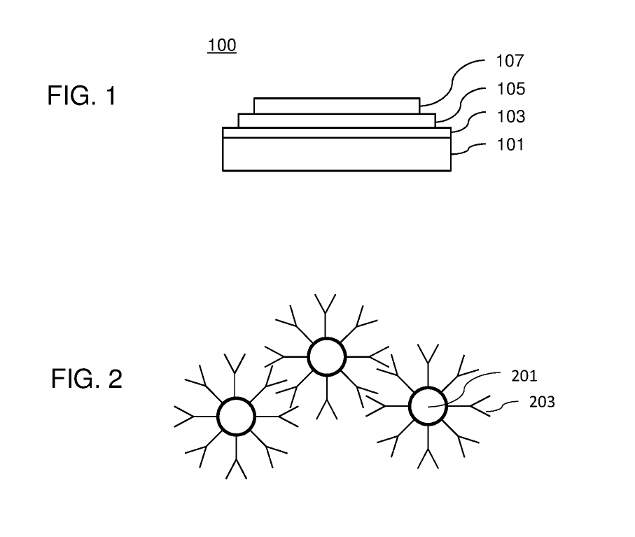

An electric device comprises at least a substrate comprising an electrically conductive layer and an electrical component. The electrically conductive layer of the substrate and the electrical component are bonded by the conductive paste. One embodiment of the method of manufacturing an electronic device 100 is explained by referring to FIG. 1. The lower limit value and the upper limit value of the numerical range in an embodiment can be combined with the upper limit value and the lower limit value of the numerical value ranges of the other different embodiments.

A substrate 101 comprising an electrically conductive layer 103 is prepared. The conductive layer 103 is may a good conductor or a semiconductor. The electrically conductive layer 103 can be an electrical circuit, an electrode or an electrical pad. The electrically conductive layer 103 may be a metal layer in another embodiment. The metal layer may comprise copper, silver, gold, nickel, palladium, platinum, or an alloy thereof in another embodiment. The electrically conductive layer 103 may be a copper layer or a silver layer in another embodiment.

The conductive paste 105 is a conductive paste for bonding. The conductive paste 105 may bond a good conductor and another good conductor, a good conductor and a semiconductor, or a semiconductor and another semiconductor. The conductive paste 105 is applied on the electrically conductive layer 103. The applied conductive paste 105 may be 50 to 500 μm thick in one embodiment, 80 to 300 μm thick in another embodiment, or 100 to 200 μm thick in still another embodiment. The conductive paste 105 is applied by screen printing in one embodiment. A metal mask may be used for the screen printing in another embodiment.

The electrical component 107 is mounted on the applied conductive paste 105. The electronic component 107 is not limited as long as it functions electrically. The electrical component 107 may be selected from the group consisting of a semiconductor chip, an integrated circuit (IC) chip, a chip resistor, a chip capacitor, a chip inductor, a sensor chip, and a combination thereof. The electrical component 107 may be a semiconductor chip in one embodiment. The semiconductor chip can be a Si chip or a SiC chip in another embodiment.

The electrical component 107 may comprise a metallization layer in one embodiment. The metallization layer may be selected from the group consisting of copper, silver, gold, nickel, palladium, platinum, an alloy thereof and a mixture thereof. The metallization layer comprises gold and/or nickel in one embodiment. The metallization layer comprises a lamination of a gold layer and a nickel layer in another embodiment. The metallization layer is in contact with the layer of the applied conductive paste 105 when the electrical component 107 comprises a metallization layer. The metallization layer is plating in another embodiment.

The layer of the instant conductive paste 105 is heated to join the conductive layer 103 and the electrical component 107. The heating temperature is 160 to 400° C. in one embodiment, 180 to 310° C. in another embodiment, and 200 to 300° C. in still another embodiment. Heating time is 0.1 to 30 minutes in one embodiment, 0.5 to 20 minutes in an another embodiment, 3 to 15 minutes in still another embodiment, 5 to 10 minutes in yet another embodiment, 0.1 to 5 minutes in an additional embodiment, 0.5 to 3 minutes in another additional embodiment, 5 to 20 minutes in yet another additional embodiment, 10 to 20 minutes in still another additional embodiment. Heat damage on the electronic component 107 is be suppressed because the conductive paste 105 is bonded at a relatively low temperature.

The heating atmosphere is an inert atmosphere or an air atmosphere. The inert atmosphere is a N₂ atmosphere in one embodiment. The heating atmosphere is an air atmosphere in another embodiment.

Pressure can be optionally applied on the electrical component 107 during the heating in an embodiment. The electrical component 107 can be better adhered to the conductive paste layer 105 by the pressure. The pressure can be at least 0.1 MPa in an embodiment, at least 1 MPa in another embodiment, at least 5 MPa in still another embodiment, at least 7 MPa in yet another embodiment, at least 15 MPa in a further embodiment, at least 25 MPa in an additional another embodiment. The pressure may be 45 MPa or lower in an embodiment, 40 MPa in another embodiment, 36 MPa or lower in still another embodiment, 25 MPa or lower in yet another embodiment, 15 MPa or lower in an additional embodiment. The electrical component 107 may be bonded without pressure in another embodiment. An oven or a die bonder can be used for heating.

The applied conductive paste 105 is optionally dried after mounting the electrical component 107 before the bonding described above. The drying temperature be 40 to 150° C. in an embodiment, 50 to 120° C. in another embodiment, and 60 to 100° C. in still another embodiment. The drying time is 10 to 150 minutes in an embodiment, 15 to 80 minutes in another embodiment, 17 to 60 minutes in still another embodiment, and 20 to 40 minutes in yet another embodiment.

The applied conductive paste 105 is optionally preheated after mounting the electrical component 107 before heating for bonding as described above. The preheating temperature is 80 to 180° C. in an embodiment, 100 to 170° C. in another embodiment, and 120 to 160° C. in still another embodiment. The preheating time is 1 second or more in an embodiment and 3 seconds or more in another embodiment. The preheating time is 60 seconds or less in an embodiment, 30 seconds or less in another embodiment, 15 seconds or less in still another embodiment, and 10 seconds or less in yet another embodiment. The electrical component 107 adheres better to the surface of the conductive paste layer 105 with preheating.

Although not restricted by a theory, it is believed that heating results in the metal powder sintering and joining the electrical component 107 and the conductive layer 103. The surface of the conductive paste layer 105 contacting the electrical component 107 is thought to get sticky so that the electrical component 107 can relatively firmly adhere to the surface of the conductive layer and be retained on the conductive paste layer 105 without peeling off.

The preheating atmosphere is a N₂ atmosphere or an air atmosphere in an embodiment. The preheating atmosphere is an air atmosphere in another embodiment.

Pre-pressure can be optionally applied on the electrical component 107 during the preheating in an embodiment. The electrical component 107 can be better adhered to the conductive paste layer 105. The pre-pressure can be at least 0.1 MPa in an embodiment, at least 0.5 MPa in another embodiment, at least 1 MPa in still another embodiment, at least 2 MPa in yet another embodiment, and at least 3 MPa in an additional embodiment. The pressure can be 10 MPa or lower in an embodiment, 8 MPa in still another embodiment, and 6 MPa or lower in yet another embodiment. The electrical component 107 can adhere to the conductive paste layer 105 without pre-pressure during the preheating in another embodiment. An oven or a die bonder can be used for preheating and pre-pressure.

The composition of the conductive paste 105 is explained hereafter. The conductive paste 105 comprises a metal powder, a solvent and a branched higher fatty acid.

### Metal Powder

The metal powder is selected from the group consisting of silver, copper, gold, palladium, platinum, rhodium, nickel, aluminum, an alloy thereof and a mixture thereof. The metal powder is selected from the group consisting of silver, copper, nickel, an alloy thereof and a mixture thereof in another embodiment. The metal powder is silver in still another embodiment.

The shape of the metal powder is in the form of flake, spherical, amorphous or a mixture thereof. The shape of the metal powder is a mixture of flake and spherical in another embodiment.

The particle diameter (D50) of the metal powder is at least 0.01 μm in one embodiment, at least 0.05 μm in another embodiment, at least 0.07 μm in still another embodiment, at least 0.1 μm in yet another embodiment, at least 0.15 μm in an additional embodiment, and at least 0.2 μm in a further embodiment. The particle diameter (D50) of the metal powder is 2 μm or less in one embodiment, 1.5 μm or less in another embodiment, 1 μm or less in still another embodiment, 0.8 μm or less in yet another embodiment, and 0.5 μm or less in an additional embodiment. With such particle diameters, the powder is well dispersed in the solvent. The metal particles with these diameters result in proper viscosity and rheology when using with the branched higher fatty acid. The branched higher fatty acid attaches to the metal powder and results in the proper distance between metal particles. The particle diameter (D50) is a volume average particle diameter (D50) measured by a laser diffraction method using Microtrac X-100.

The metal powder is 60 weight percent (wt. %) or more in an embodiment, 72 wt. % or more in another embodiment, 80 wt. % or more in still another embodiment, and 85 wt. % or more in yet another embodiment, based on the total weight of the conductive paste 105. The metal powder is 97 wt. % or less in an embodiment, 95 wt. % or less in another embodiment, 93 wt. % or less in still another embodiment, based on the total weight of the conductive paste 105.

### Solvent

The metal powder is dispersed in the solvent. The solvent can be used for adjusting the viscosity so that the conductive paste 105 can be readily applied onto the substrate 101 or the electrically conductive layer 103. All or most of the solvent evaporates from the conductive paste 105 during the heating step or the optional drying step.

The molecular weight of the solvent is 600 or less in an embodiment, 520 or less in another embodiment, 480 or less in still another embodiment, and 440 or less in yet another embodiment. The molecular weight of the solvent is 10 or more in an embodiment, 100 or more in another embodiment, 150 or more in still another embodiment, and 180 or more in yet another embodiment.

The boiling point of the solvent is 100 to 450° C. in an embodiment, 150 to 320° C. in another embodiment, and 200 to 290° C. in still another embodiment.

The solvent is an organic solvent. The solvent may be selected from the group consisting of 2,2,4-Trimethyl-1,3-pentanediol monoisobutyratetexanol (Texanol™), 1-phenoxy-2-propanol, terpineol, diethylene glycol monoethyl ether acetate (carbitol acetate), ethylene glycol, diethylene glycol monobutyl ether (butyl carbitol), diethylene glycol dibutyl ether (dibutyl carbitol), dibuthyl acetate propylene glycol phenyl ether, ethylene glycol monobutyl ether, diethylene glycol monobutyl ether acetate (butyl carbitol acetate), 1,2-cyclohexane dicarboxylic acid diisononyl ester, solvent naphtha and a mixture thereof in one embodiment. The solvent may be selected from the group consisting of 2,2,4-Trimethyl-1,3-pentanediol monoisobutyratetexanol (Texanol™), terpineol, diethylene glycol monobutyl ether (butyl carbitol), diethylene glycol monobutyl ether acetate (butyl carbitol acetate), 1,2-cyclohexane dicarboxylic acid diisononyl ester, solvent naphtha and a mixture thereof in another embodiment. The solvent may be selected from the group consisting of 2,2,4-Trimethyl-1,3-pentanediol monoisobutyratetexanol (Texanol™), terpineol, 1,2-cyclohexane dicarboxylic acid diisononyl ester and a mixture thereof in still another embodiment.

The viscosity of the conductive paste 105 is, at the shear rate of 10 sec⁻¹, 5 to 300 Pa·s in an embodiment, 9 to 200 Pa·s in another embodiment, and 12 to 100 Pa·s in still another embodiment, as measured with a rheometer (HAAKE™ MARS™ III, Thermo Fisher Scientific Inc.) using a titanium cone plate C20/1°.

The solvent is 5 to 20 parts by weight when the metal powder is 100 parts by weight. The solvent is 6.5 parts by weight or more in an embodiment, 7.8 parts by weight or more in another embodiment, and 8.8 parts by weight or more in still another embodiment when the metal powder is 100 parts by weight. The solvent is 20 parts by weight or less in an embodiment, 18 parts by weight or less in another embodiment, 15 parts by weight or less in still another embodiment, when the metal powder is 100 parts by weight.

The solvent is 2 wt. % or more in an embodiment, 4 wt. % or more in another embodiment, 6 wt. % or more in still another embodiment, and at 7.5 wt. % or more in yet another embodiment, based on the total weight of the conductive paste 105. The solvent is 25 wt. % or less in an embodiment, 20 wt. % or less in another embodiment, and 15 wt. % or less in still another embodiment, based on the total weight of the conductive paste.

### Branched Higher Fatty Acid

The branched higher fatty acid is a monovalent carboxylic acid of a long-chain hydrocarbon comprising one or more branched chains of carbon number 1 or more. The carbon number of the long-chain hydrocarbon is 12 or more. The carbon number of the branched chain is 2 or more in an embodiment, 3 or more in another embodiment, 4 or more in still another embodiment. The carbon number of the branched higher fatty acid is 14 or more in an embodiment and 16 or more in another embodiment. The carbon number of the branched higher fatty acid is 24 or less in an embodiment, 20 or less in another embodiment and 18 or less in still another embodiment.

The branched higher fatty is selected from the group consisting of n-butyloctanoic acid (C12), n-methyltridecanoic acid (C14), n-methyltetradecanoate acid (C15), isopalmitic acid (C16), isostearic acid (C18), n-methylnonadecanoic acid (C19), isoarachic acid (C20) and a mixture thereof in another embodiment.

The branched higher fatty is selected from the group consisting of isopalmitic acid (C16), isostearic acid (C18), isoarachic acid (C20) and a mixture thereof in another embodiment. Isopalmitic acid K, Isostearic acid, Isostearic acid N, Isostearic acid T, Isoarachic acid (Nissan Chemical Corporation) are available forms.

The branched higher fatty is represented with formula (I),

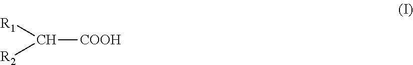

wherein R₁ and R₂ are independently hydrocarbons of carbon number 4 to 10 and the total cabon number is 12 or more in an embodiment.

Examples of R₁ and R₂ are:

R₁=n-C₇H₁₅, R₂=n-C₉H₁₉: Isostearic acid (CAS:22890-21-7),
R₁═C(CH₃)₃—CH₂—CH(CH₃)—(CH₂)₂, R₂═C(CH₃)₃—CH₂—CH(CH₃): Isostearic acid (CAS:54680-48-7),
R₁═CH₃—CH₂—CH(CH₃)—(CH₂)₅, R₂═CH₃—CH₂—CH(CH₃)—(CH₂)₃: Isostearic acid N,
R₁=n-C₈H₁₇, R₂=n-C₈H₁₇ or R₁=n-C₆H₁₃, R₂=n-C₁₀H₂₁: Isostearic acid T,
R₁═CH₃—(CH₂)₇, R₂═CH₃—(CH₂)₅: Isopalmitic acid K, and
R₁═CH₃—CH(CH₃)—(CH₂)₃—CH(CH₃)—(CH₂)₂, R₂═CH₃—CH(CH₃)—(CH₂)₃—CH(CH₃):
Isoarachic acid. Isostearic acid N, Isostearic acid T, Isopalmitic acid K and Isoarachic acid are from Nissan Chemical Corporation.

The branched higher fatty acid is 0.07 to 3 parts by weight when the metal powder is 100 parts by weight. The branched higher fatty acid is 0.08 parts by weight or more in an embodiment, 0.09 parts by weight or more in another embodiment, 0.1 parts by weight or more in still another embodiment, 0.15 parts by weight or more in yet another embodiment when the metal powder is 100 parts by weight. The branched higher fatty acid is 2.8 parts by weight or less in an embodiment, 2.2 parts by weight or less in another embodiment, 1.5 parts by weight or less in still another embodiment, 1.0 parts by weight or less in yet another embodiment, 0.7 parts by weight or less in a further embodiment and 0.5 parts by weight or less in an additional embodiment, when the metal powder is 100 parts by weight.

The branched higher fatty acid is 0.01 wt. % or more in an embodiment, 0.05 wt. % or more in another embodiment, 0.1 wt. % or more in still another embodiment, and 0.13 wt. % or more in yet another embodiment, based on the total weight of the conductive paste. The branched higher fatty acid is 3 wt. % or less in an embodiment, 2.8 wt. % or less in another embodiment, 2.2 wt. % or less in still another embodiment, 1.5 wt. % or less in yet another embodiment, 1.0 wt. % or less in a further embodiment, and 0.7 wt. % or less in an additional embodiment, and 0.5 wt. % or less in a still further embodiment, based on the total weight of the conductive paste.

### Polymer

The conductive paste 105 optionally comprises a polymer. The polymer can adjust the viscosity of the conductive paste. The polymer is soluble in the solvent. The molecular weight (Mw) of the polymer is 1,000 or more. The molecular weight of the polymer is 5,000 to 900,000 in an embodiment, 8,000 to 780,000 in another embodiment, 10,000 to 610,000 in still another embodiment, 18,000 to 480,000 in yet another embodiment, 25,000 to 350,000 in a further embodiment, and 32,000 to 200,000 in an additional embodiment. The molecular weight (Mw) is a weight average molecular weight. The molecular weight can be measured with high-performance liquid chromatography (Alliance 2695, Nippon Waters Co., Ltd.) or the like.

The polymer is selected from the group consisting of ethyl cellulose, methylcellulose, hydroxypropyl cellulose, polyvinyl butyral resin, phenoxy resin, polyester resin, epoxy resin, acrylic resin, polyimide resin, polyamide resin, polystyrene resin, butyral resin, polyvinyl alcohol resin, polyurethane resin and a mixture thereof. The polymer is a thermoplastic resin in another embodiment. The polymer is ethyl cellulose in still another embodiment.

The glass transition temperature of the polymer is −30 to 250° C. in an embodiment, 10 to 180° C. in another embodiment, and 80 to 150° C. in still another embodiment.

The polymer is 0.02 parts by weight or more in an embodiment, 0.1 parts by weight or more in another embodiment and 0.2 parts by weight or more in still another embodiment, when the metal powder is 100 parts by weight. The polymer is 4 parts by weight or less in an embodiment, 2.8 parts by weight or less in another embodiment, 1.8 parts by weight or less in still another embodiment, 1.0 parts by weight or less in yet another embodiment, and 0.7 parts by weight or less in an additional embodiment, when the metal powder is 100 parts by weight. The small amount of polymer addition can render proper viscosity while keeping the sufficient electrical conductivity of the joint layer.

The polymer is 0.01 wt. % or more in an embodiment, 0.05 wt. % or more in another embodiment, 0.1 wt. % or more in still another embodiment, and 0.15 wt. % or more in yet another embodiment, based on the total weight of the conductive paste 105. The polymer is 2 wt. % or less in an embodiment, 1 wt. % or less in another embodiment, 0.5 wt. % or less in still another embodiment, 0.3 wt. % or less in yet another embodiment, and 0.2 wt. % or less in an additional embodiment, based on the total weight of the conductive paste 105.

Although not restricted by a theory, it is believed that the branched higher fatty acid 203 attaches to the metal particles 201 and the branched side chains spreading outward from the metal particles keep a proper distance between metal particles in the conductive paste (FIG. 2). The branched higher fatty acid could make a conductive paste with a proper viscosity and rheology that can form a conductive layer with a smooth surface. The electrical component 107 could hardly be peeled off when being mounted on a smooth surface of the conductive paste layer due to an increase of the contact area.

### Additive

An additive such as a surfactant, a dispersing agent, an emulsifier, a stabilizer, and a plasticizer be can added to the conductive paste 105. The conductive paste 105 does not comprise a glass frit. The conductive paste 105 does not comprise a curing agent or a cross-linking agent. The conductive paste 105 does not comprise a thermo-setting resin.

### Examples

The present invention is illustrated by, but is not limited to, the following examples.

The conductive paste was prepared as follows.

The silver powder was dispersed in a Texanol™ solution containing the fatty acid. The silver powder was a mixture of the spherical silver powder having particle diameter (D50) of 0.3 μm and the flaky silver powder having particle diameter (D50) of 0.2 μm. The Texanol™ solution contained 13.1 parts by weight of an organic solvent and 0.3 parts by weight of ethyl cellulose. The dispersion was carried out by mixing the components in a mixer followed by a three-roll mill.

The fatty acid was an oleic acid, an isostearic acid (Nissan Chemical Corporation) or an isostearic acid T (Nissan Chemical Corporation). The comparative example contained no fatty acid.

The viscosity of the conductive paste was 15 to 70 Pa·s at the shear rate of 10 sec⁻¹. The viscosity was measured by a rheometer (HAAKE™ MARS™ III, titanium cone-plate:C20/1°, Thermo Fisher Scientific Inc.).

Next, the conductive paste layer was formed by applying the conductive paste on a copper substrate. Scotch Tape™ (Magic™, MP-18, 3M corporation) was put on the copper plate (25 mm wide, 34 mm long, 1 mm thick) with a spacing of 10 mm. The conductive paste was applied with a scraper over the Scotch Tapes to fill the space with the conductive paste. The Scotch Tape™ was peeled off. The square pattern (10 mm wide, 10 mm long, 150 μm thick) of the conductive paste layer was formed. The conductive paste layer was dried at 80° C. for 30 minutes in an oven with an air atmosphere.

The surface of the square pattern was rated OK when the surface was smooth or NG when the surface was rough with concave and convex areas by visual observation. The gap between the mounted electrical component and the square pattern showed good adherence to the substrate when the pattern surface was smooth.

The adhesion was examined after drying the conductive paste of the square pattern. A copper chip (3 mm wide, 3 mm long, 1 mm thick) was mounted on the square pattern after drying. The copper chip was adhered to the square pattern of the conductive paste layer by using a die-bonder (T-3002M, Tresky AG) under the preheating and pre-pressure of 5 MPa/150° C./5 seconds in the air atmosphere. The adhesion was rated NG when the copper chip peeled off at a touch of a pincette, OK when the copper chip was rigid at a touch of a pincette.

Next, the mounted copper chip was bonded to the copper plate by using a die-bonder (T-3002M, Tresky AG) under the heating and pressure of 10 MPa/280° C./1 minute in the air atmosphere. The bonding strength between the copper chip and the copper plate was measured by die shear test (MIL-STD-883) with a bond-tester (4000 Plus, Nordson Advanced Technology). The bonding strength when the copper chip peeled off by the bond-tester was recorded.

The results are shown in Table 1. The adhesion was sufficient when the conductive paste contained the fatty acid (Comparative Example 2, Example 1 and 2) while the adhesion was so insufficient as the copper chip easily peeled off before heating to bond when the conductive paste did not contain the fatty acid (Comparative Example 1). The conductive paste layer of the square pattern containing no fatty acid did not have a smooth surface and the bonding strength was low, 37 MPa (Comparative Example 1). The conductive paste containing the oleic acid did not form the smooth surface and the bonding strength was low, 47 MPa (Comparative Example 2). The conductive paste layer containing the isostearic acid or the isostearic acid T had smooth surface and the bonding strength was sufficiently high to be 50 MPa or more respectively (Example 1 and 2)

TABLE 1
(parts by weight)

| | Comparative | Comparative | | |
|---|---|---|---|---|
| | Example 1 | Example 2 | Example 1 | Example 2 |
| Ag powder | 100 | 100 | 100 | 100 |
| Texanol ™ solution | 13.6 | 13.4 | 13.4 | 13.4 |
| Oleic Acid | 0 | 0.2 | 0 | 0 |
| Isostearic acid | 0 | 0 | 0.2 | 0 |
| Isostearic acid T | 0 | 0 | 0 | 0.2 |
| Pattern Surface | NG | NG | OK | OK |
| Adhesion | NG | OK | OK | OK |
| Bonding Strength | 37 | 47 | 53 | 60 |
| (MPa) | | | | |

Next, the amount of the branched higher fatty acid, the isostearic acid T, was examined. The conductive paste was prepared in the same manner as Example 2 except for the amount of the isostearic acid T and the adhesion and pattern surface was rated likewise. The pattern surface was smooth as the isostearic acid T was added. The adhesion was insufficient so that the copper chip peeled off when the isostearic acid T was 0.06 parts by weight (Comparative Example 3). The adhesion of the copper was sufficient enough to hold the copper chip on the conductive paste layer before heating to bond when the isostearic acid T was 0.1 parts by weight (Example 3).

TABLE 2
(parts by weight)

| | Comparative | |
|---|---|---|
| | Example 3 | Example 3 |
| Ag powder | 100 | 100 |
| Texanol ™ solution | 13.4 | 13.4 |
| Isostearic acid T | 0.06 | 0.1 |
| Pattern Surface | NG | OK |
| Adhesion | OK | OK |

Next, the use of decanoic acid and isopalmitic acid as fatty acids were examined. The conductive paste was prepared in the same manner as Example 1 except for changing the fatty acid and the adhesion and pattern surface was rated likewise. The copper chip adhered to the conductive paste layer although the pattern surface was not smooth when using the decanoic acid (Comparative Example 4). The pattern surface was smooth and the adhesion was sufficient when using the isopalmitic acid (Example 4).

TABLE 3
(parts by weight)

| | Comparative | |
|---|---|---|
| | Example 4 | Example 4 |
| Ag powder | 100 | 100 |
| Texanol ™ solution | 13.4 | 13.4 |
| Decanoic acid | 0.2 | 0 |
| Isopalmitic acid | 0 | 0.2 |
| Pattern Surface | NG | OK |
| Adhesion | OK | OK |

The Example above shows that the electrical component was firmly bonded to the conductive layer by using the conductive paste. The electrical component mounted on the applied conductive layer adheres sufficiently during the manufacturing process, especially before heating to bond.

What is claimed is:

1. A method of manufacturing an electronic device comprising the steps of:
preparing a substrate comprising an electrically conductive layer;
applying a conductive paste on the electrically conductive layer; wherein the conductive paste comprises 100 parts by weight of a metal powder, 5 to 20 parts by weight of a solvent, and 0.07 to 3 parts by weight of a branched higher fatty acid;
mounting an electrical component on the applied conductive paste; and
heating the conductive paste to bond the electrically conductive layer and the electrical component.

2. The method of claim 1, wherein the branched higher fatty is selected from the group consisting of n-butyloctanoic acid (C12), n-methyltridecanoic acid (C14), n-methyltetradecanoate acid (C15), isopalmitic acid (C16), isostearic acid (C18), n-methylnonadecanoic acid (C19), isoarachic acid (C20) and a mixture thereof.

3. The method of claim 1, wherein the branched higher fatty is selected from the group consisting of isopalmitic acid (C16), isostearic acid (C18), isoarachic acid (C20) and a mixture thereof.

4. The method of claim 1, wherein the branched higher fatty is represented with formula (I), 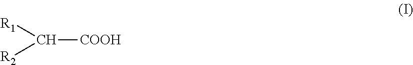
wherein R₁ and R₂ are independently hydrocarbons of carbon number 4 to 10 and the total carbon number is 12 or more.

5. The method of claim 1, wherein the particle diameter (D50) of the metal powder is 0.01 to 2 μm.

6. The method of claim 1, wherein the conductive paste further comprises 0.01 to 4 parts by weight of a polymer.

7. The method of claim 1, wherein the heating temperature to bond the electronic component and the conductive layer is 160 to 400° C.

8. The method of claim 1, wherein the electrical component is selected from the group consisting of a semiconductor chip, an integrated circuit (IC) chip, a chip resistor, a chip capacitor, a chip inductor, a sensor chip, and a combination thereof.

9. The method of claim 1, wherein the electrical component comprises a metallization layer selected from the group consisting of copper, silver, gold, nickel, palladium, platinum, alloy thereof and a mixture thereof.

10. A conductive paste for bonding, comprising 100 parts by weight of the metal powder, 5 to 20 parts by weight of a solvent, and 0.07 to 3 parts by weight of a branched higher fatty acid.

11. The conductive paste of claim 10, wherein the branched higher fatty is selected from the group consisting of n-butyloctanoic acid (C12), n-methyltridecanoic acid (C14), n-methyltetradecanoate acid (C15), isopalmitic acid (C16), isostearic acid (C18), n-methylnonadecanoic acid (C19), isoarachic acid (C20) and a mixture thereof.

12. The conductive paste of claim 10, wherein the branched higher fatty is selected from the group consisting of isopalmitic acid (C16), isostearic acid (C18), isoarachic acid (C20) and a mixture thereof.

13. The conductive paste of claim 10, wherein the branched higher fatty is represented with formula (I), 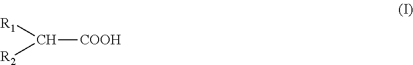
wherein R₁ and R₂ are independently hydrocarbons of carbon number of 4 to 10 and the total carbon number is 12 or more.

14. The conductive paste of claim 10, wherein the particle diameter (D50) of the metal powder is 0.01 to 2 μm.

15. The conductive paste of claim 10, wherein the conductive paste further comprises 0.01 to 4 parts by weight of a polymer.
